(19) United States
(12) Patent Application Publication
(10) Pub. No.: US 2010/0012960 A1
(43) Pub. Date: Jan. 21, 2010

(54) LIGHT EMITTING DIODE

(75) Inventor: CHIA-SHOU CHANG, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: FOXCONN TECHNOLOGY CO., LTD., Tu-Cheng (TW)

(21) Appl. No.: 12/465,587

(22) Filed: May 13, 2009

(30) Foreign Application Priority Data
Jul. 18, 2008 (CN) 200810302796.0

(51) Int. Cl. H01L 33/00

(52) U.S. Cl. 257/98; 257/E33.067

(57) ABSTRACT

An LED includes a substrate, an LED die, and a packaging layer. The substrate has conductive pins extending therethrough. The LED die is arranged on the substrate and electronically connected to the conductive pins of the substrate. The packaging layer couples to the substrate to encapsulate the LED die therein. The packaging layer includes a contacting surface attached to the substrate, an outer surface opposite to the contacting surface and facing an ambient air, and a lateral surface between the contacting surface and the outer surface. The lateral surface of the packaging layer converges from the contacting surface to the outer surface. A refractive index of the packaging layer decreases from the contacting surface to the outer surface.

### BACKGROUND

1. Technical Field

The disclosure generally relates to light emitting diodes, and particularly to a light emitting diode with a high light extracting rate.

2. Description of Related Art

In recent years, LEDs are preferred for use in illumination devices rather than CCFLs (cold cathode fluorescent lamps) due to their excellent properties, including high brightness, long lifespan, wide color range, etc.

Generally, each LED includes an LED die and a packaging layer encapsulating the LED die. The packaging layer is made of transparent materials, such as epoxy resin and silica gel. A refractive index of the packaging layer is about 1.5. However, the ambient air around the packaging layer has a refractive index about 1.0. Snell's Law tells us that a critical angle is about 42 degrees. In other words, the light with an angle of incidence smaller than 42 degrees can pass across the packaging layer to the ambient air, whilst the light with an angle of incidence not smaller than 42 degrees generates total reflection at a boundary of the packaging layer and the ambient air, and then travels back to the packaging layer. Thus only a small part of the light of the LED die can pass through the packaging layer into ambient air for lighting, i.e., a light extracting rate of the LED is very low. Accordingly, a utilization efficiency of the light of the LED is relatively low, and needs to be raised.

For the foregoing reasons, therefore, there is a need in the art for an LED which overcomes the limitations described.

### BRIEF DESCRIPTION OF THE DRAWINGS

FIG. 1 is an isometric, assembled view of a light emitting diode (LED) according to an exemplary embodiment.

FIG. 2 is a cross sectional view of the LED taken along line II-II of FIG. 1.

FIG. 3 is similar to FIG. 2, but showing an LED according to an alternative embodiment.

FIG. 4 is a cross sectional view of an LED according to a third embodiment.

FIG. 5 is a cross sectional view of an LED according to a fourth embodiment.

### DETAILED DESCRIPTION

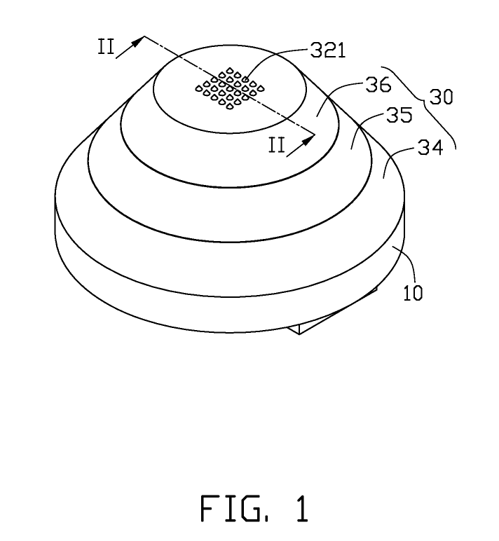

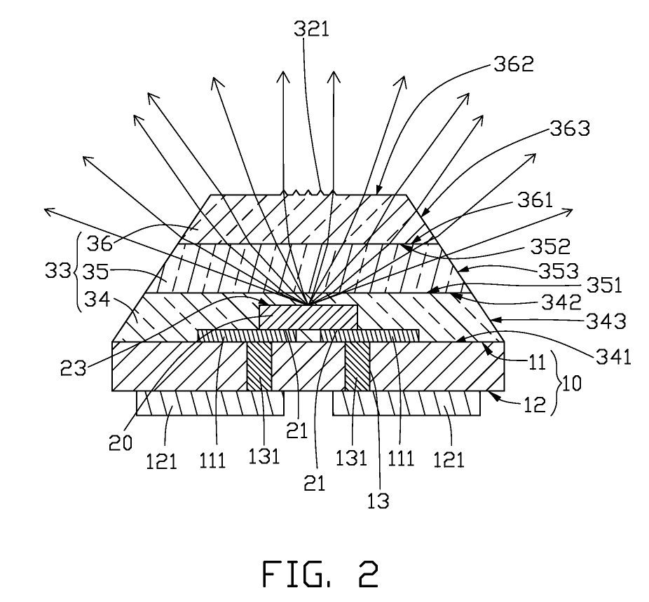

Referring to FIGS. 1 and 2, a light emitting diode (LED) according to an exemplary embodiment includes a substrate 10, an LED die 20 for generating light, and a packaging layer 30 encapsulating the LED die 20 therein for protecting the LED die 20 from environmental harm or mechanical damage.

The substrate 10 is disc-shaped, and includes an upper side 11 and a lower side 12 opposite to the upper side 11. Both of the upper and lower sides 11, 12 of the substrate 10 are flat. The substrate 10 defines a pair of mounting holes 13 near a center thereof. The mounting holes 13 are spaced from each other, and extend through the substrate 10 vertically from the upper side 11 to the lower side 12. Each mounting hole 13 receives a conductive pin 131 therein.

A pair of outer terminals 121 are formed on the lower side 12 of the substrate 10 corresponding to the conductive pins 131, respectively. Each outer terminal 121 is located under and electrically connected to a bottom end of the corresponding conductive pin 131. The two outer terminals 121 are insulated and spaced from each other. Similarly, a pair of inner terminals 111 are formed on the upper side 11 of the substrate 10 corresponding to the conductive pins 131, respectively. Each inner terminal 111 is located over and electrically connected to a top end of the corresponding conductive pin 131. The two inner terminals 111 are insulated and spaced from each other. Thus each inner terminal 111 is connected to the corresponding outer terminal 121 electrically, and is insulated from the other inner terminal 111 and the other outer terminal 121.

The LED die 20 is arranged on the upper side 11 of the substrate 10, and coaxially located on a center of the substrate 10. The LED die 20 forms an emitting surface 23 at a top side thereof, and has a pair of electrodes 21 formed at a bottom side thereof for connecting with a power source. The LED die 20 is arranged above the two inner terminals 111 with the electrodes 21 thereof connecting to the inner terminals 111 of the substrate 10, respectively. Thus the electrodes 21 of the LED die 20 are respectively electrically connected to the outer terminals 121 through the inner terminals 111 and the conductive pins 131.

The packaging layer 30 is coupled to the upper side 11 of the substrate 10 to encapsulate the LED die 20 therein. The packaging layer 30 is made of transparent materials, such as silica gel or epoxy resin. The packaging layer 30 is substantially truncated conical, and has a cross section decreasing in size upwardly and gradually along an axial direction thereof. In this embodiment, the packaging layer 30 includes three parts, i.e., a bottom part 34, a middle part 35, and a top part 36, stacked upwardly along the axial direction of the packaging layer 30. It is to be understood that the packaging layer 30 is not limited to be three parts.

Each of the three parts 34, 35, 36 is truncated conical with a vertical cross section being trapezoid, and includes a lower surface 341, 351, 361, an upper surface 342, 352, 362 parallel to the lower surface 341, 351, 361, and a lateral surface 343, 353, 363 interconnecting outer peripheries of the upper surface 342, 352, 362 and the lower surface 341, 351, 361. The upper surface 342, 352, 362 and the lower surface 341, 351, 361 of each part 34, 35, 36 of the packaging layer 30 are circular. A size of the upper surface 342, 352, 362 of each part 34, 35, 36 is smaller than that of the lower surface 341, 351, 361. The lateral surface 343, 353, 363 of each part 34, 35, 36 converges from the lower surface 341, 351, 361 to the upper surface 342, 352, 362. An angle defined between the lateral surface 343, 353, 363 and the lower surface 341, 351, 361 of each part 34, 35, 36 in the packaging layer 30 is the same as that of the other parts 34, 35, 36, being less than 90 degrees.

The lower surface 341 of the bottom part 34 of the packaging layer 30 acts as a bottom surface of the packaging layer 30, and is attached to the upper side 11 of the substrate 10. The lower surface 341 of the bottom part 34 has a size and a shape substantially equaling to those of the upper side 11 of the substrate 10, and covering the upper side 11 of the substrate 10 entirely. A cavity (not labeled) depresses inwardly from a central portion of the lower surface 341 of the bottom part 34 for accommodating the LED die 20 and the inner terminals 111 therein.

The middle part 35 is arranged on the upper surface 342 of the bottom part 34. The lower surface 351 of the middle part 35 of the packaging layer 30 is the same as that of the upper surface 342 of the bottom part 34, and overlaps with the upper surface 342 of the bottom part 34. The top part 36 is arranged on the upper surface 352 of the middle part 35 with the lower surface 361 thereof overlapping the upper surface 352 of the middle part 35. Cooperatively the lateral surfaces 343, 353, 363 of the three parts 34, 35, 36 form a glazed lateral surface of the packaging layer 30. The upper surface 362 of the top part 36 acts as a top surface of the packaging layer 30, and faces an ambient air. A plurality of micro-protrusions 321 are integrally formed on the upper surface 362 of the top part 36 for enhancing spread of the light of the LED die 20 to let a light field of the LED to be more even.

Each of the three parts 34, 35, 36 of the packaging layer 30 has a plurality of particles evenly distributed therein for adjusting a light refractive index thereof. The particles can be nano-particles, such as titanium oxide, tantalum dioxide, silicon oxide, or molecule particles, such as phenol. The bottom part 34 has more particles than the middle part 35, and the top part 36 has fewer particles than the middle part 35. The refractive index of the middle part 35 is lower than that of the bottom part 34, but is larger than that of the top part 36. The refractive index of the top part 36 is slightly larger than that of the ambient air around the packaging layer 30. Thus the packaging layer 30 has a refractive index decreasing upwardly to the ambient air. A difference of the refractive indexes between two neighboring parts 34, 35, 36 of the packaging layer 30 is decreased along the bottom-to-top direction.

During operation, the two outer terminals 121 of the LED die 20 are connected to the power source for supplying current to the LED die 20 to cause it to emit light. As the difference of the refractive indexes between two neighboring parts 34, 35, 36 of the packaging layer 30 is decreased, a critical angle to generate a total reflection at a boundary of two neighboring parts 34, 35, 36 is increased. Therefore, more light can pass through the three parts 34, 35, 36 of the packaging layer 30 to the ambient air for lighting. In addition, as the lateral surface of the packaging layer 30 converging upwardly, an incident angle of the light which travels to the lateral surface is much increased, and thus the light traveling to the lateral surface of the packaging layer 30 can travel therethrough to the ambient air. Therefore, more light of the LED die 20 can pass through the packaging layer 30 to the ambient air through either the top surface or the lateral surface thereof. A light extracting rate of the LED is thus enhanced. Correspondingly, a utilization efficiency of the light of the LED is improved.

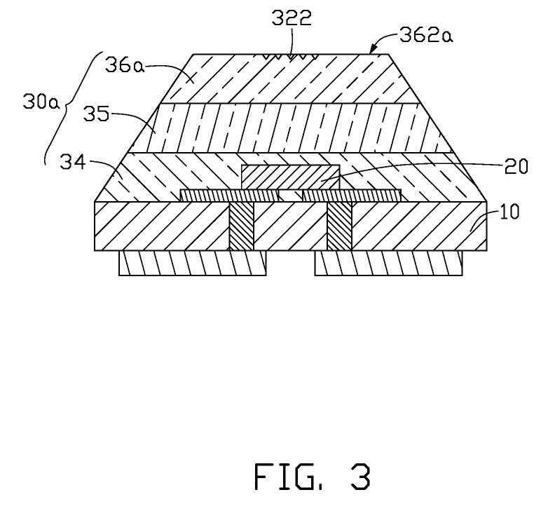

FIG. 3 shows an LED in accordance with an alternative embodiment, except the top part 36a of the packaging layer 30a, the substrate 10, the LED die 20, the bottom part 34 and the middle part 35 of the packaging layer 30a of the LED of this embodiment are substantially the same as that of the previous LED shown in FIGS. 1 and 2. In this embodiment, a plurality of micro-cavities 322 are concaved inwardly from the upper surface 362a of the top part 36a of the packaging layer 30a, i.e., concaved from the top surface of the packaging layer 30. Similar to the micro-protrusions 321, the micro-cavities 322 can enhance dispersion of the light of the LED die 20.

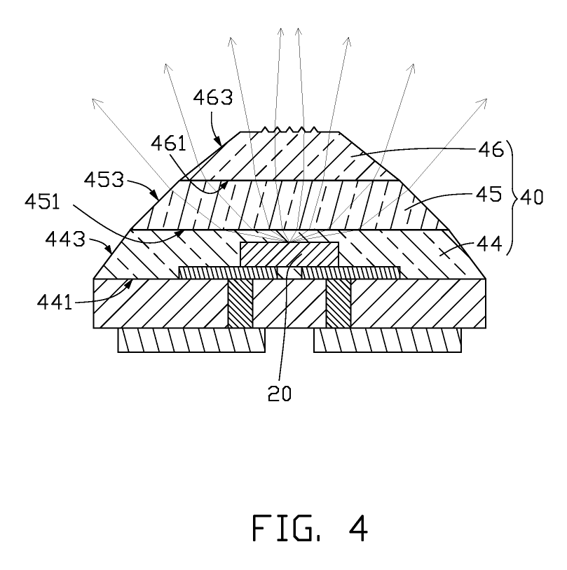

Referring to FIG. 4, an LED with a packaging layer 40 differing from the previous embodiments is shown. Similar to the previous embodiments, the packaging layer 40 includes three parts 44, 45, 46. Each part 44, 45, 46 has a shape of truncated conical. A cross section of each part 44, 45, 46 is trapezoid, and decreases upwardly and gradually along an axial direction of the packaging layer 40. The difference is that an angle defined between a lateral surface 443, 453, 463 and a lower surface 441, 451, 461 of each part 44, 45, 46 of the packaging layer 40 of this embodiment is different from that of the other parts 44, 45, 46. The angle of the bottom part 44 is larger than that of the middle part 45, and the angle of the middle part 45 is lager than that of the top part 46. In other words, the angle of the three parts 44, 45, 46 of the packaging layer 40 decreases upwardly.

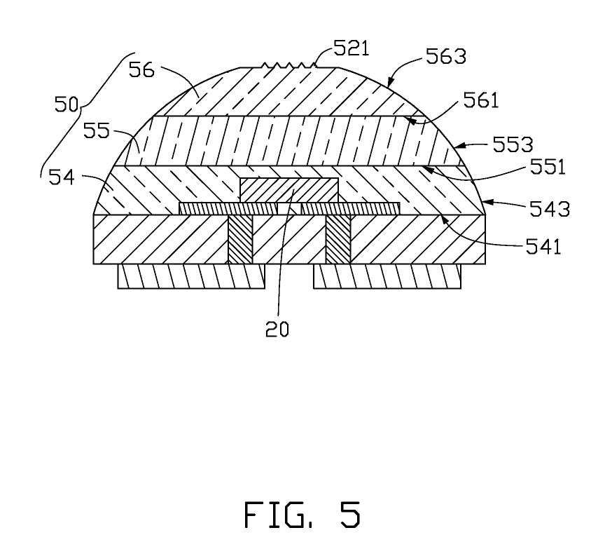

FIG. 5 shows an LED in accordance with a fourth embodiment. In this embodiment, the packaging lager 50 of the LED has a shape of inverted bowl. Similarly, the packaging layer 50 has a number of parts 54, 55, 56 stacked along an axial direction thereof. Cooperatively, lateral surfaces 543, 553, 563 of the parts 54, 55, 56 form a glazed lateral surface of the packaging layer 50. Each part 54, 55, 56 has an angle defined between the lateral surface 543, 553, 563 and the lower surface 541, 551, 561 thereof decreasing gradually and upwardly, and an angle defined between the lateral surface and the bottom surface of the packaging layer 50 decreases upwardly along the axial direction of the packaging layer 50.

It is to be understood, however, that even though numerous characteristics and advantages of the disclosure have been set forth in the foregoing description, together with details of the structure and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A light emitting diode (LED), comprising:
an LED die for emitting light outwardly; and
a packaging layer encapsulating the LED die, the packaging layer comprising a plurality of parts stacked along an axial direction thereof, a size of a cross section of the packaging layer decreasing outwardly along the axial direction thereof, and a refractive index of the plurality of stacked parts decreasing outwardly along the axial direction of the packaging layer.

2. The LED of claim 1, wherein each part of the packaging layer comprising a first surface, a second surface parallel to the first surface, and a lateral surface interconnecting outer peripheries of the first surface and the second surface, a size of the first surface being smaller than that of the second surface, the lateral surface converging from the second surface to the first surface, cooperatively the lateral surfaces of the plurality of parts forming a lateral surface of the packaging layer, the first surface of one of the plurality of parts having a smallest size forming an outer surface of the packaging layer facing an ambient air.

3. The LED of claim 2, wherein the LED die is arranged in one of the plurality of parts having a largest size, and has an emitting surface facing the outer surface of the packaging layer, light of the LED die travelling through the lateral surface and the outer surface of the packaging layer to the ambient air.

4. The LED of claim 3, wherein the packaging layer is substantially truncated conical, and each part of the packaging layer is substantially truncated conical, an angle defined between the lateral surface and the second surface of each part being the same as that of the other parts.

5. The LED of claim 4, wherein contacting surfaces of two neighboring parts of the packaging layer have the same shape and size, and overlap with each other, the lateral surfaces of the plurality parts cooperatively forming a glazed lateral surface of the packaging layer.

6. The LED of claim 3, wherein the packaging layer is substantially truncated conical, and each part of the packaging layer is substantially truncated conical, an angle defined between the lateral surface and the second surface of each part being different from that of the other parts, the angle of the plurality of parts decreasing outwardly from the one of the plurality of parts having the largest size to the one of the plurality of parts having the smallest size.

7. The LED of claim 3, wherein the packaging layer has a shape of an inverted bowl, an angle defined between the lateral surface of the packaging layer and the second surface of the one of the plurality of parts having the largest size decreases gradually outwardly to the outer surface of the packaging layer.

8. The LED of claim 3, wherein a plurality of micro-protrusions are formed on the outer surface of the packaging layer.

9. The LED of claim 3, wherein a plurality of micro-cavities are defined in the outer surface of the packaging layer.

10. The LED of claim 3, wherein a plurality of particles are distributed in each of the plurality of parts for adjusting the refractive index of the plurality of parts of the packaging layer, the particles are selected from one of titanium oxide, tantalum dioxide, silicon oxide and phenol, and a density of the particles in the plurality of parts decreases outwardly from the one of the plurality of parts having the largest size to the one of the plurality of parts having the smallest size

11. A light emitting diode (LED), comprising:
a substrate having conductive pins extending therethrough for electronically connecting to a power source;
an LED die arranged on the substrate and electronically connected to the conductive pins of the substrate; and
a packaging layer coupling to the substrate to encapsulate the LED die therein, the packaging layer having a contacting surface attached to the substrate, an outer surface opposite to the contacting surface and facing an ambient air, and a lateral surface between the contacting surface and the outer surface, the lateral surface of the packaging layer converging from the contacting surface to the outer surface, a refractive index of the packaging layer decreasing from the contacting surface to the outer surface.

12. The LED of claim 11, wherein the packaging layer comprises a plurality of parts stacked together along an axial direction thereof, a refractive index of each part is different from that of the other parts.

13. The LED of claim 12, wherein the packaging layer is substantially truncated conical, an angle defined between the lateral surface and the contacting surface of the packaging layer is constant.

14. The LED of claim 12, wherein the packaging layer is substantially truncated conical, an angle defined between the lateral surface and the contacting surface of the packaging layer in each part is constant, and is different from that of the other parts.

15. The LED of claim 12, wherein the packaging layer has a shape of an inverted bowl, and an angle defined between the lateral surface and the contacting surface of the packaging layer decreases gradually from the contacting surface to the outer surface.

16. The LED of claim 11, wherein a plurality of micro-protrusions are formed on the outer surface of the packaging layer.

17. The LED of claim 11, wherein a plurality of micro-cavities are defined in the outer surface of the packaging layer.
